(19) United States
(12) Patent Application Publication
(10) Pub. No.: US 2025/0208610 A1
(43) Pub. Date: Jun. 26, 2025

(54) SUBSTRATE PROCESSING APPARATUS AND SUBSTRATE PROCESSING METHOD

(71) Applicant: Tokyo Electron Limited, Tokyo (JP)

(72) Inventors: Takashi NAGAI, Koshi City (JP); Hisashi MORITA, Koshi City (JP)

(73) Assignee: Tokyo Electron Limited, Tokyo (JP)

(21) Appl. No.: 18/986,780

(22) Filed: Dec. 19, 2024

(30) Foreign Application Priority Data
Dec. 20, 2023 (JP) 2023-214663

(51) Int. Cl. G05B 19/418

(52) U.S. Cl. CPC G05B 19/41865; G05B 2219/45031

(57) ABSTRACT

A substrate processing apparatus includes a substrate processing device for immersing a substrate in a phosphoric acid aqueous solution; and circuitry for controlling the substrate processing device. The substrate processing device includes: a processing tub including an inner tub in which the phosphoric acid aqueous solution is stored and an outer tub for collecting the phosphoric acid aqueous solution; a circulation line for sending the phosphoric acid aqueous solution taken out from the outer tub into the inner tub; a liquid level sensor for detecting a liquid level of the phosphoric acid aqueous solution in the outer tub; and a pure water supply for supplying pure water into the processing tub. The substrate is immersed in the phosphoric acid aqueous solution in the inner tub. The circuitry controls a supply flow rate of the pure water based on a detection value of the liquid level.

### CROSS-REFERENCE TO RELATED APPLICATION

This application claims the benefit of Japanese Patent Application No. 2023-214663 filed on Dec. 20, 2023, the entire disclosures of which are incorporated herein by reference.

### TECHNICAL FIELD

The various aspects and embodiments described herein pertain generally to a substrate processing apparatus and a substrate processing method.

### BACKGROUND

Patent document 1 describes a method of controlling a boiling state of a phosphoric acid aqueous solution. In this method, the boiling state of the phosphoric acid aqueous solution is quantitatively evaluated based on a back pressure when an inert gas is purged in the phosphoric acid aqueous solution.

Patent document 2 describes a technique of correcting a phosphoric acid concentration of the phosphoric acid aqueous solution according to an atmospheric pressure. The higher the atmospheric pressure is, the lower the phosphoric acid concentration is set.
Patent Document 1: Japanese Patent Laid-open Publication No. 2004-153164
Patent Document 2: Japanese Patent Laid-open Publication No. 2016-039352

### SUMMARY

In one or more embodiments of the present application, a substrate processing apparatus includes a substrate processing device configured to immerse a substrate in a phosphoric acid aqueous solution; and a controller configured to control the substrate processing device. The substrate processing device includes: a processing tub including an inner tub in which the phosphoric acid aqueous solution is stored and an outer tub configured to collect the phosphoric acid aqueous solution overflowing from the inner tub; a circulation line configured to send the phosphoric acid aqueous solution taken out from the outer tub into the inner tub; a liquid level sensor configured to detect a liquid level of the phosphoric acid aqueous solution in the outer tub; and a pure water supply configured to supply pure water into the processing tub. The substrate is immersed in the phosphoric acid aqueous solution in the inner tub. The controller controls a supply flow rate of the pure water based on a detection value of the liquid level.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating a substrate processing apparatus according to one or more embodiments of the present application;

FIG. 2 is a diagram showing an example of a concentration control and a flow rate control;

FIG. 3 is a diagram showing an example of a relationship between H2 and V;

FIG. 4 is a diagram showing an example of a relationship between N and ΔH2 (ΔH2=H2a−H2b);

FIG. 5 is a diagram showing an example of a relationship between N and A;

FIG. 6 is a diagram showing an example of a relationship between A and H2;

FIG. 7 is a diagram showing an example of changes in C, Q and H2 over time during the flow rate control;

FIG. 8 is a diagram illustrating a substrate processing apparatus according to a modification example; and

FIG. 9 is a diagram showing an example of timing for concentration controls in a plurality of substrate processing devices.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the one or more embodiments of the present application. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, one or more embodiments of the present application will be described with reference to the accompanying drawings. In the various drawings, same or corresponding parts will be assigned same reference numerals, and redundant descriptions thereof will be omitted. In the present specification, the X-axis, Y-axis and Z-axis directions are perpendicular to each other. The X-axis direction and the Y-axis direction are horizontal directions, and the Z-axis direction is a vertical direction. The X-axis direction includes the positive X-axis direction, and the negative X-axis direction which is a direction opposite to the positive X-axis direction. The Y-axis direction includes the positive Y-axis direction, and the negative Y-axis direction which is a direction opposite to the positive Y-axis direction. The Z-axis direction includes the positive Z-axis direction, and the negative Z-axis direction which is a direction opposite direction to the positive Z-axis direction. In the present specification, a supply flow rate means a supply amount per unit time.

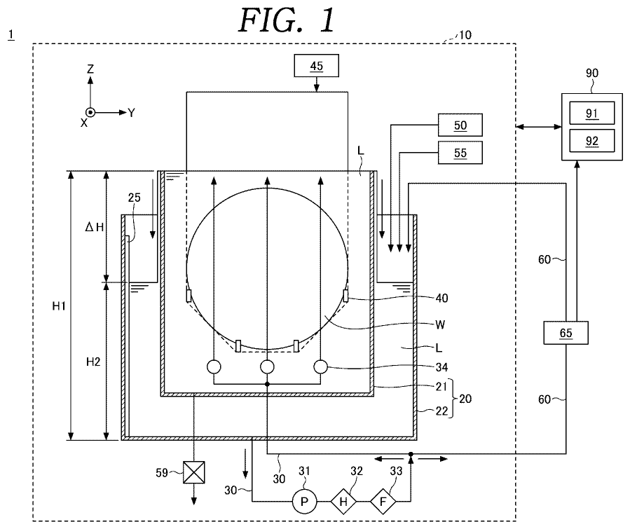

As depicted in FIG. 1, a substrate processing apparatus 1 includes a substrate processing device 10 configured to immerse a substrate W in a phosphoric acid aqueous solution L, and a controller 90 configured to control the substrate processing device 10. The substrate W includes a silicon oxide film and a silicon nitride film, and the phosphoric acid aqueous solution L selectively etches the silicon nitride film between the silicon oxide film and the silicon nitride film. The phosphoric acid aqueous solution L includes phosphoric acid and water.

The substrate processing device 10 includes a processing tub 20. The processing tub 20 includes an inner tub 21 in which the phosphoric acid aqueous solution L is stored, and an outer tub 22 configured to collect the phosphoric acid aqueous solution L that has overflowed from the inner tub 21. In the substrate processing device 10, the substrate W is immersed in the phosphoric acid aqueous solution L in the inner tub 21. The liquid level of the phosphoric acid aqueous solution L in the inner tub 21 is the same as the height of an upper end of the inner tub 21.

The substrate processing device 10 is equipped with a circulation line 30. The circulation line 30 sends the phosphoric acid aqueous solution L taken out from the outer tub 22 into the inner tub 21. The phosphoric acid aqueous solution L that has overflowed from the inner tub 21 is recovered into the outer tub 22. The liquid level of the phosphoric acid aqueous solution L in the outer tub 22 changes when the substrate W is immersed in the phosphoric acid aqueous solution L and when it is not immersed.

The substrate processing device 10 is equipped with a pump 31, a temperature regulator 32, and a filter 33 in the circulation line 30. The pump 31 force-feeds the phosphoric acid aqueous solution L. The temperature regulator 32 adjusts the temperature of the phosphoric acid aqueous solution L. The temperature regulator 32 includes a heater. The temperature of the phosphoric acid aqueous solution L is set to, for example, a boiling point of the phosphoric acid aqueous solution L. The filter 33 collects particles contained in the phosphoric acid aqueous solution L.

The substrate processing device 10 is equipped with a plurality of horizontal pipes 34 at a leading end of the circulation line 30. The horizontal pipes 34 extend in the X-axis direction, and are arranged at a certain distance therebetween in the Y-axis direction. Each horizontal pipe 34 has a multiple number of discharge openings spaced apart from each other in the lengthwise direction thereof. Each of the multiple number of discharge openings discharges the phosphoric acid aqueous solution L upwards, forming a curtain-shaped ascending flow inside the inner tub 21.

The substrate processing device 10 includes a substrate holder 40 and an elevating device 45. The substrate holder 40 holds the substrate W. For example, the substrate holder 40 holds a plurality of substrates W at a certain distance therebetween in the X-axis direction, while keeping each substrate W vertically upright. The elevating device 45 moves the substrate holder 40 up and down between an immersion position where the substrate W is immersed in the phosphoric acid aqueous solution L and a standby position where the substrate W is lifted from the phosphoric acid aqueous solution L.

The substrate processing device 10 includes a pure water supply 50 and a phosphoric acid supply 55. The pure water supply 50 supplies pure water into the processing tub 20 (desirably, the outer tub 22). The phosphoric acid supply 55 supplies phosphoric acid into the processing tub 20 (desirably, the outer tub 22). Each of the pure water supply 50 and the phosphoric acid supply 55 has, by way of example, an opening/closing valve and a flow rate controller.

The substrate processing device 10 is equipped with a draining device 59. The draining device 59 drains the phosphoric acid aqueous solution L to the outside of the substrate processing apparatus 1. In the present exemplary embodiment, the draining device 59 drains the phosphoric acid aqueous solution L from a bottom of the inner tub 21. Alternatively, however, the phosphoric acid aqueous solution L may be discharged from the circulation line 30. The draining device 59 includes, by way of example, an opening/closing valve and a flow rate controller.

The draining device 59 drains at least some of the phosphoric acid aqueous solution L periodically. Thereafter, the phosphoric acid supply 55 supplies the phosphoric acid to the processing tub 20, and the pure water supply 50 supplies the pure water to the processing tub 20, thereby preparing the phosphoric acid aqueous solution L. Supply amounts of the phosphoric acid and the pure water are previously set.

The controller 90 is, by way of example, a computer, and includes an operation unit 91 such as a CPU (Central Processing Unit) and a storage 92 such as a memory. The storage 92 stores a program that controls various processes performed in the substrate processing apparatus 1. The controller 90 controls the operation of the substrate processing apparatus 1 by causing the operation unit 91 to execute the program stored in the storage 92. The functionality of the elements disclosed herein may be implemented using circuitry or processing circuitry which includes general purpose processors, special purpose processors, integrated circuits, ASICs (“Application Specific Integrated Circuits”), FPGAS (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The phosphoric acid aqueous solution L contains phosphoric acid and water. The water has a boiling point lower than that of the phosphoric acid. During the boiling of the phosphoric acid aqueous solution L, the water is selectively evaporated. The substrate processing apparatus 1 may be provided with an inspection line 60 and a concentration sensor 65. The inspection line 60 branches off from the circulation line 30 downstream of the temperature regulator 32 and sends the phosphoric acid aqueous solution L flowing through the circulation line 30 to the outer tub 22. Due to the presence of the inspection line 60, retention of the phosphoric acid aqueous solution L can be suppressed, so that a temperature decrease of the phosphoric acid aqueous solution L can be suppressed. The concentration sensor 65 detects a phosphoric acid concentration C of the phosphoric acid aqueous solution L flowing through the inspection line 60. The concentration sensor 65 detects the phosphoric acid concentration C of the phosphoric acid aqueous solution L by detecting, for example, a refractive index of the phosphoric acid aqueous solution L.

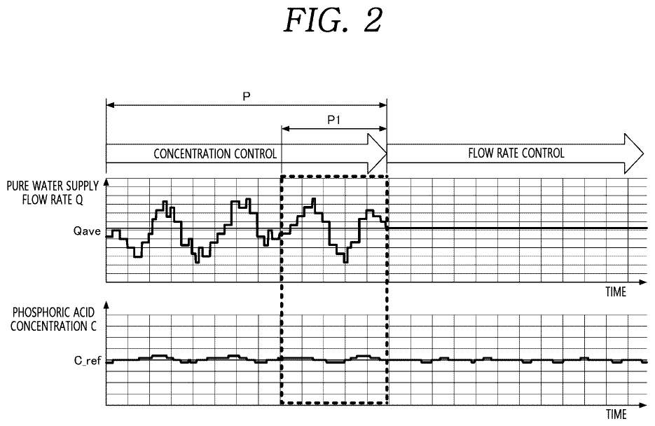

After the phosphoric acid aqueous solution L is prepared, the controller 90 performs the following concentration control (see FIG. 2). The concentration control is a feedback control, and controls a supply flow rate Q of the pure water such that a detection value C_det of the phosphoric acid concentration C becomes a set value C_ref. Here, Q is a supply flow rate of the water supplied by the pure water supply 50 to the processing tub 20. The concentration control is performed in the state that the substrate W is not immersed in the phosphoric acid aqueous solution L in the inner tub 21 and the phosphoric acid supply 55 has stopped the supply of the phosphoric acid. Also, the concentration control is performed in the state that the temperature of the phosphoric acid aqueous solution L is stabilized.

The controller 90 may correct the set value C_ref of the phosphoric acid concentration C according to an atmospheric pressure. When the phosphoric acid concentration C is the same, the higher the atmospheric pressure, the higher the boiling point of the phosphoric acid aqueous solution L. Meanwhile, when the atmospheric pressure is the same, the lower the phosphoric acid concentration C, the lower the boiling point of the phosphoric acid aqueous solution L. With a rise of the atmospheric pressure, the controller 90 reduces the phosphoric acid concentration C, thereby maintaining the temperature of the phosphoric acid aqueous solution L constant and the boiling state (for example, the size and number of bubbles) of the phosphoric acid aqueous solution L constant. Here, the temperature of the phosphoric acid aqueous solution L is maintained constant because it takes time to change the temperature of the phosphoric acid aqueous solution L due to its large volume and large heat capacity.

The controller 90 calculates an average value Qave of the supply flow rate Q of the pure water during at least a partial period P1 in a period P during which the concentration control is performed. The average value Qave corresponds to an evaporation amount V of the water per unit time in the phosphoric acid aqueous solution L. It is desirable that the controller 90 calculates the average value Qave during the partial period P1 in the period P during which the concentration control is performed. It is desirable that the partial period P1 is a period (for example, 5 minutes) immediately before an end of the period P during which the concentration control is performed. The period is, however, not limited to 5 minutes.

Upon the completion of the concentration control, the controller 90 performs the following flow rate control (see FIG. 2). The flow rate control is performed to control the supply flow rate Q of the pure water based on the calculated average value Qave of the supply flow rate Q of the pure water. By way of example, the controller 90 fixes the supply flow rate Q of the pure water to the average value Qave. This makes it possible to suppress fluctuations in the phosphoric acid concentration C without having to refer to the detection value C_det of the phosphoric acid concentration C. Therefore, as will be described in detail later, it is possible to suppress the fluctuations in the phosphoric acid concentration C in a plurality of substrate processing devices 10 by using the single concentration sensor 65.

During the flow rate control, the controller 90 not only fixes the supply flow rate Q of the pure water to the average value Qave but also can correct the supply flow rate Q of the pure water based on the average value Qave. By way of example, during the flow rate control, the controller 90 may correct the supply flow rate Q of the pure water according to a variation amount ΔH2 of a liquid level H2 of the phosphoric acid aqueous solution L in the outer tub 22. This is because, as will be described in detail later, the evaporation amount V of the water per unit time in the phosphoric acid aqueous solution L depends on the liquid level H2.

The evaporation amount V of the water per unit time in the phosphoric acid aqueous solution L depends on an area of an interface between the phosphoric acid aqueous solution L and the atmosphere. The larger the area of the interface between the phosphoric acid aqueous solution L and the atmosphere, the larger the evaporation amount V. The interface between the phosphoric acid aqueous solution L and the atmosphere includes a liquid surface of the phosphoric acid aqueous solution L in the inner tub 21 and a liquid surface of the phosphoric acid aqueous solution L in the outer tub 22. The areas of these liquid surfaces are constant.

The interface between the phosphoric acid aqueous solution L and the atmosphere also includes a lateral surface of the phosphoric acid aqueous solution L falling down from the upper end of the inner tub 21 along a side surface of the inner tub 21. The area of the lateral surface is proportional to a drop of the phosphoric acid aqueous solution L falling down. The drop is equal to a height difference ΔH (ΔH=H1−H2) between a liquid level H1 of the phosphoric acid aqueous solution L in the inner tub 21 and the liquid level H2 of the phosphoric acid aqueous solution L in the outer tub 22. Since H1 is constant, ΔH depends on H2. Reference points for H1 and H2 are not particularly limited as long as they are at the same height.

The higher the liquid level H2 of the phosphoric acid aqueous solution L in the outer tub 22, the smaller the height difference ΔH and the smaller the area of the interface between the phosphoric acid aqueous solution L and the atmosphere. Therefore, the higher the liquid level H2, the smaller the evaporation amount V. The inventors of the present application have noted that the higher the liquid level H2 is, the smaller the evaporation amount V is. The liquid level H2 may vary when immersing or lifting the substrate W, or when carrying-out the phosphoric acid aqueous solution L adhering to the substrate W.

The substrate processing device 10 includes a liquid level sensor 25. The liquid level sensor 25 detects the liquid level H2 of the phosphoric acid aqueous solution L in the outer tub 22. The controller 90 controls the supply flow rate Q of the pure water based on a detection value H2_det of the liquid level H2. Therefore, even if the evaporation amount V fluctuates due to fluctuations in the liquid level H2, the pure water can be replenished at the flow rate corresponding to the evaporation amount V. Thus, fluctuations in the phosphoric acid concentration C can be suppressed without using the concentration sensor 65.

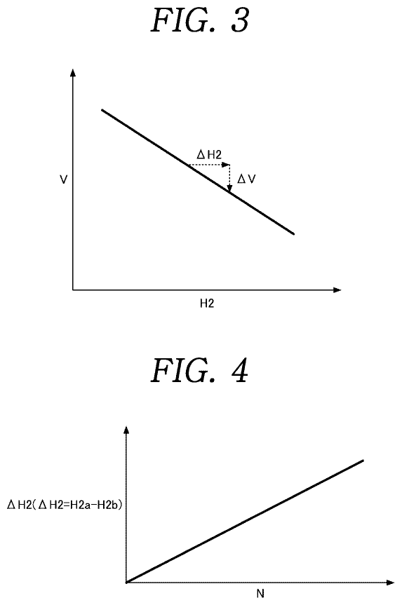

The controller 90 previously stores a relationship between the liquid level H2 and the evaporation amount V (for example, the relationship shown in FIG. 3). Here, V is expressed by a linear equation of H2. This is because V is proportional to the area of the interface between the phosphoric acid aqueous solution L and the atmosphere, and this area is expressed by the linear equation of H2. The controller 90 controls Q based on the previously stored relationship between H2 and V and H2_det. By way of example, the controller 90 calculates V by substituting H2_det as a value of H2 into the previously stored relationship between H2 and V, and controls Q such that Q becomes equal to the calculated V.

The controller 90 may perform the following liquid level control to obtain the relationship between H2 and V. The liquid level control is a feedback control, and controls the supply flow rate Q of the pure water such that the detection value H2_det of the liquid level H2 becomes a set value H2_ref. Q that fixes H2 is V. The liquid level control is performed in the state that the substrate W is not immersed in the phosphoric acid aqueous solution L in the inner tub 21 and the phosphoric acid supply 55 has stopped the supply of phosphoric acid. Also, the liquid level control is performed in the state that the temperature of the phosphoric acid aqueous solution L is stabilized.

In order to obtain the relationship between H2 and V, the controller 90 repeats the above-described liquid level control while changing the set value H2_ref of the liquid level H2. At this time, it is desirable to gradually decrease the set value H2_ref of the liquid level H2. Just by draining some of the phosphoric acid aqueous solution L to the outside of the substrate processing apparatus 1 by the draining device 59 before and after the controller 90 changes the set value H2_ref of the liquid level H2, it is possible to reduce the liquid level H2 while maintaining the phosphoric acid concentration C constant.

As stated above, the evaporation amount V is expressed by the linear equation of the liquid level H2. Therefore, a ratio R_{ΔV/ΔH2} (R_{ΔV/ΔH2}=ΔV/ΔH2) of a variation amount ΔV of the evaporation amount V to the variation amount ΔH2 of the liquid level H2 is constant (negative).

The controller 90 may store the ratio RΔV/ΔH2 in advance and correct the supply flow rate Q of the pure water based on the ratio R_{ΔV/ΔH2} and a variation amount ΔH2_det of H2_det. The correction amount may be a product R_{ΔV/ΔH2}×ΔH2_det of the ratio R_{ΔV/ΔH2} and the variation amount ΔH2_det. Even if the liquid level H2 fluctuates and the evaporation amount V thus fluctuates, the pure water can be replenished at the flow rate corresponding to the evaporation amount V.

The controller 90 may correct the supply flow rate Q of the pure water only when ΔH2_det falls below a lower limit or exceeds an upper limit. The lower limit and the upper limit are determined in consideration of a detection error of H2. The correction of Q may be performed multiple times until H2 is stabilized. Further, if H2 is not stabilized even after Q is corrected a set number of times, the controller 90 may stop correcting Q and perform a control of setting off an alarm.

The controller 90 may perform a correction of reducing the supply flow rate Q of the pure water when the substrate W is immersed in the phosphoric acid aqueous solution L in the inner tub 21. When the substrate W is immersed in the phosphoric acid aqueous solution L, the phosphoric acid aqueous solution L in an amount corresponding to the volume of the substrate W overflows from the inner tub 21 into the outer tub 22. As a result, the liquid level H2 of the phosphoric acid aqueous solution L in the outer tub 22 increases, and the evaporation amount V of the water per unit time in the phosphoric acid aqueous solution L decreases. By reducing the supply flow rate Q of the pure water, the pure water can be replenished at the flow rate corresponding to the evaporation amount V, so that the fluctuation in the phosphoric acid concentration C can be suppressed.

The controller 90 may calculate the correction amount (decrement) of Q during the immersion based on a number N of substrates W immersed in the phosphoric acid aqueous solution L. As shown in FIG. 4, ΔH2 (ΔH2=H2a−H2b) is proportional to the number N of the substrates W. Here, H2a is H2 immediately after the immersion, and H2b is H2 immediately before the immersion. A ratio R_{ΔH2}/N (R_{ΔH2}/N=ΔH2/N) of ΔH2 to N is constant.

By way of, the controller 90 stores R_{ΔH2}/N in advance, and calculates a decrement of Q during the immersion based on R_{ΔH2}/N, R_{ΔV/ΔH2}, and N. The value of the decrement is, for example, an absolute value of a product of R_{ΔH2}/N, R_{ΔV/ΔH2}, and N (R_{ΔH2}/N×R_{ΔV/ΔH2}×N). During the immersion of the substrates W, the pure water can be replenished at the flow rate corresponding to the evaporation amount V, so that the fluctuation in the phosphoric acid concentration C can be suppressed.

Also, the controller 90 may perform a correction of increasing the supply flow rate Q of the pure water when the substrate W is lifted from the phosphoric acid aqueous solution L. When the substrate W is lifted from the phosphoric acid aqueous solution L, the phosphoric acid aqueous solution L in an amount corresponding to the volume of the substrate W is sent from the outer tub 22 into the inner tub 21. As a result, the liquid level H2 of the phosphoric acid aqueous solution L in the outer tub 22 decreases, and the evaporation amount V of the water per unit time in the phosphoric acid aqueous solution L increases. By increasing the supply flow rate Q of the pure water, the pure water can be replenished at the flow rate corresponding to the evaporation amount V, so that the fluctuation in the phosphoric acid concentration C can be suppressed.

For example, the controller 90 may calculate the correction amount (increment) of Q during the lifting based on the number N of the substrates W immersed in the phosphoric acid aqueous solution L. By way of example, the controller 90 stores R_{ΔH2}/N in advance, and calculates the increment of Q during the lifting based on R_{ΔH2}/N, R_{ΔV/ΔH2}, and N. Although the value of the increment of Q during the lifting can be equal to the value of the decrement of Q during the immersion, it is desirable that the value of the increment is larger than the value of the decrement.

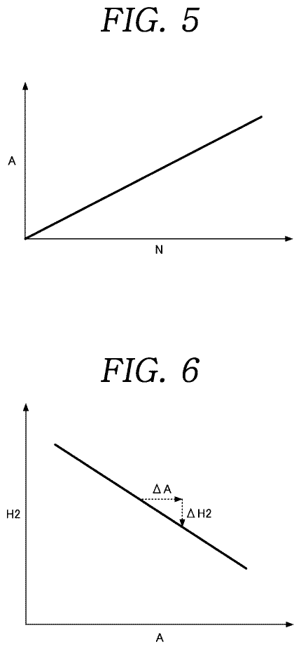

When lifting the substrate W from the phosphoric acid aqueous solution L, the phosphoric acid aqueous solution L adhering to the substrate W is carried out to the outside of the processing tub 20. A carry-out amount A is proportional to the number of the substrates W (see FIG. 5). This is because the amount of the phosphoric acid aqueous solution L adhering to the substrates W is proportional to the number of the substrates W. As shown in FIG. 5, a ratio R_{A/N} (R_{A/N}=A/N) of A to N is constant. Also, as shown in FIG. 6, the liquid level H2 of the phosphoric acid aqueous solution L in the outer tub 22 decreases with a rise of the carry-out amount A of the phosphoric acid aqueous solution L. A ratio R_{ΔH2/ΔA} (R_{ΔH2/ΔA}=Δ_{H2/ΔA}) of ΔH2 to ΔA is constant.

Therefore, the controller 90 may calculate the correction amount (increment) of Q during the lifting based on the carry-out amount A. The value of the increment is, for example, the sum of an absolute value of the product (R_{ΔH2}/N×R_{ΔV/ΔH2}×N) of R_{ΔH2}/N, R_{ΔV/ΔH2}, and N and an absolute value of the product (R_{ΔH2/ΔA}×R_{A/N}×N×R_{ΔV/ΔH2}) of R_{ΔH2/ΔA}, R_{A/N}, N, and R_{ΔV/ΔH2}. The value of increment of Q during the lifting is larger than the value of the decrement of Q during the immersion by the product (R_{ΔH2/ΔA}×R_{A/N}×N×R_{ΔV/ΔH2}).

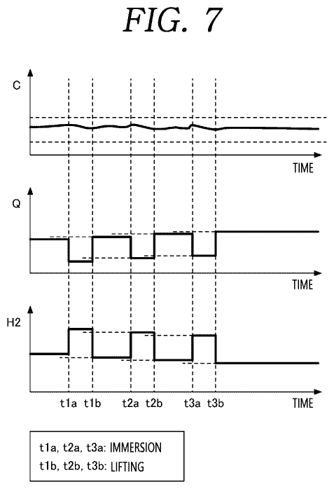

Next, referring to FIG. 7, an example of changes in the phosphoric acid concentration C, the pure water supply flow rate Q, and the liquid level H2 over time during the flow rate control will be explained. The controller 90 monitors the liquid level H2 with the liquid level sensor 25 during the flow rate control, and controls the pure water supply flow rate Q based on the liquid level H2. During the immersion, since the liquid level H2 increases, the controller 90 reduces the pure water supply flow rate Q. Furthermore, during the lifting, since the liquid level H2 decreases, the controller 90 increases the pure water supply flow rate Q. Further, during the lifting, since the phosphoric acid aqueous solution L adhering to the substrate W is carried out of the processing tub 20 by the substrate W, the liquid level H2 becomes lower than that before the immersion. Therefore, it is desirable that the value of the increment of Q during the lifting is larger than the value of the decrement of Q during the immersion. In this way, by controlling the pure water supply flow rate Q based on the liquid level H2, it is possible to suppress the fluctuation in the phosphoric acid concentration C without referring to the detection value C_det of the phosphoric acid concentration C.

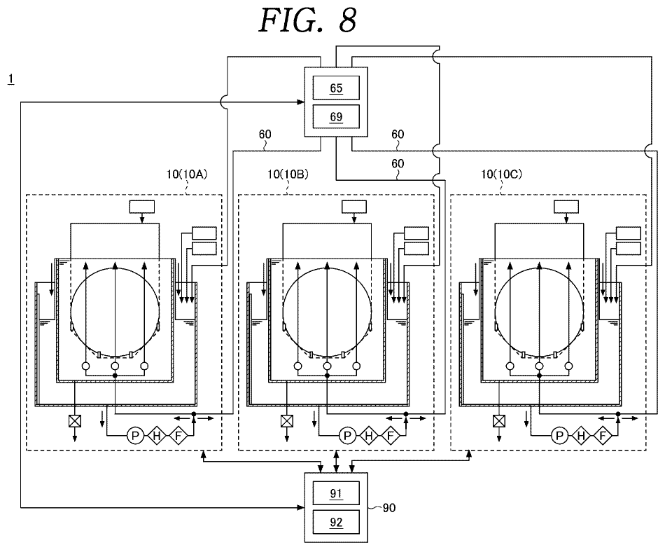

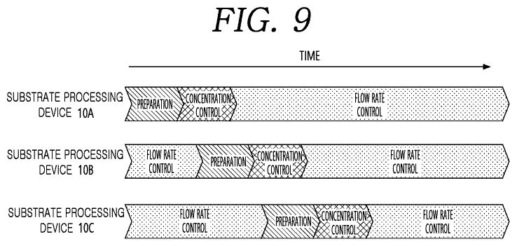

Next, referring to FIG. 8 and FIG. 9, a modification example of the substrate processing apparatus 1 will be explained. Below, distinctive features from the above-described exemplary embodiment will be mainly explained. The substrate processing apparatus 1 includes a plurality of substrate processing devices 10, and the inspection line 60 is provided for each substrate processing device 10. Further, the substrate processing apparatus 1 is also equipped with the concentration sensor 65 and a switching valve 69 configured to switch the inspection line 60 led to the concentration sensor 65. With this configuration, it is possible to suppress the fluctuation in the phosphoric acid concentration C in the plurality of substrate processing devices 10 by using the single concentration sensor 65.

As illustrated in FIG. 9, in order to suppress an overlap of periods during which the concentration control is performed in the respective substrate processing devices 10A, 10B, and 10C, the controller 90 creates schedules for the preparation of the phosphoric acid aqueous solution L, the concentration control, and the flow rate control for each of the substrate processing devices 10A, 10B, and 10C. The schedule for the flow rate control includes a schedule for the immersion of the substrate W. The controller 90 performs the preparation of the phosphoric acid aqueous solution L, the concentration control, and the flow rate control according to the created schedules. Therefore, the processing efficiency of the substrate W can be improved.

When abnormality occurs in the phosphoric acid concentration C, introduction of a unprocessed substrate W into the substrate processing device 10 where the abnormality has occurred is stopped, and draining of the phosphoric acid aqueous solution L and preparation of the phosphoric acid aqueous solution L are performed. Thereafter, the concentration control and the flow rate control are performed in this order in the substrate processing device 10 where the abnormality has occurred. In this way, the immersion of the substrate W is performed during the flow rate control.

So far, the exemplary embodiment of the substrate processing apparatus and the substrate processing method according to the present disclosure have been described. However, the present disclosure is not limited to the above-described exemplary embodiment and the like. Various changes, modifications, substitutions, additions, deletions and combinations may be made within the scope of the claims, which are all incorporated within a technical scope of the present disclosure.

According to the exemplary embodiment, it is possible to suppress the fluctuations in the phosphoric acid concentration in the phosphoric acid aqueous solution.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus comprising:
a substrate processing device configured to immerse a substrate in a phosphoric acid aqueous solution; and
circuitry configured to control the substrate processing device,
wherein the substrate processing device comprises:
a processing tub including an inner tub in which the phosphoric acid aqueous solution is stored and an outer tub configured to collect the phosphoric acid aqueous solution overflowing from the inner tub;
a circulation line configured to send the phosphoric acid aqueous solution taken out from the outer tub into the inner tub;
a liquid level sensor configured to detect a liquid level H2 of the phosphoric acid aqueous solution in the outer tub; and
a pure water supply configured to supply pure water into the processing tub,
the substrate is immersed in the phosphoric acid aqueous solution in the inner tub, and
the circuitry controls a supply flow rate Q of the pure water based on a detection value H2_det of the liquid level H2.

2. The substrate processing apparatus of claim 1,
wherein the circuitry is configured to store in memory of the substrate processing apparatus a relationship between the liquid level H2 and an evaporation amount V of water per unit time in the phosphoric acid aqueous solution in advance, and control the supply flow rate Q of the pure water based on the relationship and the detection value H2_det.

3. The substrate processing apparatus of claim 2,
wherein the circuitry is configured to store in the memory a ratio R_{ΔV/ΔH2} (R_{ΔV/ΔH2}=ΔV/ΔH2) of a variation amount ΔV of the evaporation amount V to a variation amount ΔH2 of the liquid level H2, and correct the supply flow rate Q of the pure water based on the ratio R_{ΔV/ΔH2} and a variation amount of the detection value H2_det.

4. The substrate processing apparatus of claim 1,
wherein the circuitry is configured to perform a correction of reducing the supply flow rate Q of the pure water when the substrate is immersed in the phosphoric acid aqueous solution, and a correction of increasing the supply flow rate Q of the pure water when the substrate is lifted from the phosphoric acid aqueous solution.

5. The substrate processing apparatus of claim 4,
wherein the substrate includes multiple substrates, and the circuitry is configured to calculate a correction amount of the supply flow rate Q of the pure water based on a number N of the multiple substrates.

6. The substrate processing apparatus of claim 4,
wherein the circuitry is configured to calculate a correction amount of the supply flow rate Q of the pure water based on an amount A of the phosphoric acid aqueous solution carried out of the processing tub by the substrate when the substrate is lifted from the phosphoric acid aqueous solution.

7. The substrate processing apparatus of claim 1,
wherein the substrate processing device includes multiple substrate processing devices, and an inspection line, the inspection line being branched from the circulation line and configured to send the phosphoric acid aqueous solution flowing through the circulation line to the outer tub, is provided for each of the multiple substrate processing devices, and
the substrate processing apparatus further comprises a concentration sensor configured to detect a phosphoric acid concentration C in the phosphoric acid aqueous solution flowing through the inspection line, and a switching valve configured to switch the inspection line led to the concentration sensor.

8. The substrate processing apparatus of claim 7,
wherein the substrate processing device comprises a phosphoric acid supply configured to supply phosphoric acid to the processing tub, and
the circuitry is configured to perform a concentration control of controlling the supply flow rate Q of the pure water such that a detection value C_det of the phosphoric acid concentration C becomes a set value C_ref in a state that the substrate is not immersed in the phosphoric acid aqueous solution in the inner tub and the phosphoric acid supply has stopped supply of the phosphoric acid.

9. The substrate processing apparatus of claim 8,
wherein the circuitry is configured to perform a calculation control of calculating an average value of the supply flow rate of the pure water in at least a part of a period during which the concentration control is performed, and perform, after the concentration control, a flow rate control of controlling the supply flow rate of the pure water based on the calculated average value.

10. The substrate processing apparatus of claim 9,
wherein the circuitry is configured to perform the calculation control of calculating the average value of the supply flow rate of the pure water in a part of the period during which the concentration control is performed, and
the part of the period is a period immediately before an end of the period during which the concentration control is performed.

11. The substrate processing apparatus of claim 8,
wherein periods during which the concentration control is performed in the multiple substrate processing devices do not overlap.

12. A substrate processing method, comprising:
immersing, by using a substrate processing apparatus as claimed in claim 1, the substrate in the phosphoric acid aqueous solution in the inner tub.

13. The substrate processing method of claim 12, further comprising:
storing in memory a relationship between the liquid level H2 and an evaporation amount V of water per unit time in the phosphoric acid aqueous solution in advance; and
controlling the supply flow rate Q of the pure water based on the relationship and the detection value H2_det.

14. The substrate processing method of claim 13, further comprising:
storing in the memory a ratio R_{ΔV/ΔH2} (R_{ΔV/ΔH2}=ΔV/ΔH2) of a variation amount ΔV of the evaporation amount V to a variation amount ΔH2 of the liquid level H2; and
correcting the supply flow rate Q of the pure water based on the ratio R_{ΔV/ΔH2} and a variation amount of the detection value H2_det.

15. The substrate processing method of claim 12, further comprising:
performing a correction of reducing the supply flow rate Q of the pure water when the substrate is immersed in the phosphoric acid aqueous solution; and
performing a correction of increasing the supply flow rate Q of the pure water when the substrate is lifted from the phosphoric acid aqueous solution.

16. The substrate processing method of claim 15,
wherein the substrate includes multiple substrates, and the method further comprises calculating a correction amount of the supply flow rate Q of the pure water based on a number N of the multiple substrates.

17. The substrate processing method of claim 15, further comprising:
calculating a correction amount of the supply flow rate Q of the pure water based on an amount A of the phosphoric acid aqueous solution carried out of the processing tub by the substrate when the substrate is lifted from the phosphoric acid aqueous solution.

18. The substrate processing method of claim 12,
wherein the substrate processing device includes multiple substrate processing devices, and an inspection line, the inspection line being branched from the circulation line and configured to send the phosphoric acid aqueous solution flowing through the circulation line to the outer tub, is provided for each of the multiple substrate processing devices, and
the method further comprises:
detecting, by a concentration sensor, a phosphoric acid concentration C in the phosphoric acid aqueous solution flowing through the inspection line; and
switching, by a switching valve, the inspection line led to the concentration sensor.

19. The substrate processing method of claim 18, further comprising:
supplying, by a phosphoric acid supply, phosphoric acid to the processing tub, and
performing a concentration control of controlling the supply flow rate Q of the pure water such that a detection value C_det of the phosphoric acid concentration C becomes a set value C_ref in a state that the substrate is not immersed in the phosphoric acid aqueous solution in the inner tub and the phosphoric acid supply has stopped supply of the phosphoric acid.

20. The substrate processing method of claim 19,
further comprising performing calculation control of calculating an average value of the supply flow rate of the pure water in at least a part of a period during which the concentration control is performed, and perform, after the concentration control, a flow rate control of controlling the supply flow rate of the pure water based on the calculated average value.
